(19) United States
(12) Patent Application Publication
(10) Pub. No.: US 2022/0119601 A1
(43) Pub. Date: Apr. 21, 2022

(54) METHOD OF MANUFACTURING COLOR CONVERSION FILM, COLOR CONVERSION FILM THEREOF, AND DISPLAY PANEL

(71) Applicant: Shenzhen China Star Optoelectronics Semiconductor Display Technology Co., Ltd., Shenzhen (CN)

(72) Inventor: Yongwei WU, Shenzhen (CN)

(73) Assignee: Shenzhen China Star Optoelectronics Semiconductor Display Technology Co., Ltd., Shenzhen (CN)

(21) Appl. No.: 16/769,247

(22) PCT Filed: Apr. 14, 2020
(86) PCT No.: PCT/CN2020/084721

§ 371 Date: Jun. 3, 2020

(30) Foreign Application Priority Data
Mar. 30, 2020 (CN) 202010237455.0

(51) Int. Cl. C08J 5/18; B29D 11/00; G02B 5/22; G02B 1/04; H01L 33/50

(52) U.S. Cl. CPC C08J 5/18; B29D 11/00634; G02B 5/223; G02B 1/04; H01L 33/502; C08J 2371/02; C08J 2329/04; C08J 2329/10; C08J 2333/12; C08J 2367/02; C08J 2325/06

(57) ABSTRACT

A color conversion film and a manufacturing method thereof are provided. The manufacturing method includes following steps: forming a composite solution comprising of a first type polymer, a second type polymer, a color conversion material, and a first solvent into a film, wherein the first type polymer is selected from a group consisting of water-soluble polymers and oil-soluble polymers, and the second type polymer is selected from another group consisting of water-soluble polymers and oil-soluble polymers; and immersing the film in a second solvent to remove the second type polymer.

### FIELD OF INVENTION

The present application relates to a field of display, and in particular to a method of manufacturing a color conversion film, the color conversion film, and a display panel.

### BACKGROUND OF INVENTION

Quantum dots are used in display screens due to their characteristics of high luminous efficiency, narrow emission spectrum, and coverage of full spectrum of visible light. Quantum dot TVs on the market utilize usage of excellent light-emitting properties of quantum dot materials as a color conversion layer on a light-outputting surface of a blue backlight. Through excitation of the blue backlight, red and green with high color purity are obtained, thereby further improving color gamut of an entire display screen. However, due to factors such as interference between adjacent quantum dots, poor light absorption, and poor light extraction rate, light efficiency of pure quantum dot films is low, which directly affects power utilization and display brightness of display devices.

### SUMMARY OF INVENTION

### Technical Problem

In view of abovementioned, a purpose of the present application is to provide a color conversion film capable of improving light conversion efficiency, a manufacturing method thereof, and a display panel.

### Technical Solution

The present application provides a method of manufacturing a color conversion film, which includes following steps:

forming a composite solution comprising of a first type polymer, a second type polymer, a color conversion material, and a first solvent into a film, wherein the first type polymer is selected from a group consisting of water-soluble polymers and oil-soluble polymers, and the second type polymer is selected from another group consisting of water-soluble polymers and oil-soluble polymers; and

immersing the film in a second solvent, wherein the second type polymer is removed, and the color conversion film is obtained after drying.

In an embodiment of the present application, a mass fraction of the first type polymer is greater than a mass fraction of the second type polymer.

In an embodiment of the present application, the first type polymer is oil-soluble polymers, the second type polymer is water-soluble polymers, and the color conversion material is an oil-soluble material.

In an embodiment of the present application, the mass fraction of the first type polymer ranges from 10% to 25%, the mass fraction of the second type polymer ranges from 2% to 8%, and a mass fraction of the color conversion material ranges from 1% to 10%.

In an embodiment of the present application, a solvent of a first solution is a polar aprotic solvent, and the second solvent is a polar protic solvent.

In an embodiment of the present application, the first type polymer is water-soluble polymers, the second type polymer is oil-soluble polymers, and the color conversion material is a water-soluble material.

In an embodiment of the present application, the oil-soluble polymers are selected from one or more of polyethylene terephthalate, polymethyl methacrylate, and polystyrene.

In an embodiment of the present application, the water-soluble polymers are selected from one or more of polyethylene glycol, polyvinyl alcohol, polyvinyl ether, and polyethylene oxide.

The present application further provides a color conversion film, the color conversion film includes a porous skeleton composed of a first type polymer and a color conversion material embedded in pores of the porous skeleton, and the first type polymer is selected from a group consisting of water-soluble polymers and oil-soluble polymers.

The present application further provides a display panel, which includes a first substrate, a second substrate, and a blue light-emitting layer and a color conversion film disposed between the first substrate and the second substrate, wherein the color conversion film is disposed on a light-outputting surface of the blue light-emitting layer, the color conversion film includes a porous skeleton composed of a first type polymer and a color conversion material embedded in pores of the porous skeleton, and the first type polymer is selected from a group consisting of water-soluble polymers and oil-soluble polymers.

### Beneficial Effect

Compared with the conventional art, the method of manufacturing a color conversion film of the present application uses two types of polymers with a color conversion material and a first solvent to form a composite solution to construct a uniform and continuous film, and one type of mixture is removed by a second solvent to form pores in the film, while the color conversion material remains in the pores. The continuous, uniform, and loose porous structure can enhance the color conversion material, such as the absorption of incident light by the color conversion material. At the same time, it can increase the light extraction rate of the excitation light of the color conversion material, and has a significant effect on improving the light efficiency of a color conversion film layer.

### BRIEF DESCRIPTION OF FIGURES

In order to illustrate the technical solutions of the present application or the related art in a clearer manner, the drawings desired for the present application or the related art will be described hereinafter briefly. Obviously, the following drawings merely relate to some embodiments of the present application, and based on these drawings, a person skilled in the art may obtain the other drawings without any creative effort.

FIG. 1 is a flowchart of a method of manufacturing a color conversion film according to a first embodiment of the present application.

FIG. 2 is a schematic structural diagram of a display panel according to a second embodiment of the present application.

### DETAILED DESCRIPTION OF EMBODIMENTS

The following content combines with the drawings and the embodiment for describing the present application in detail. It is obvious that the following embodiments are merely some embodiments of the present application, but not all the embodiments. Based on the embodiments in the present application, for the skilled persons of ordinary skill in the art without creative effort, the other embodiments obtained thereby are still covered by the present application.

A first embodiment of the present application provides a color conversion film and a method of manufacturing the same, the color conversion film can be used in a display panel using blue organic light-emitting diodes or blue micro light-emitting diodes (micro light-emitting diode display, micro LED) as a backlight.

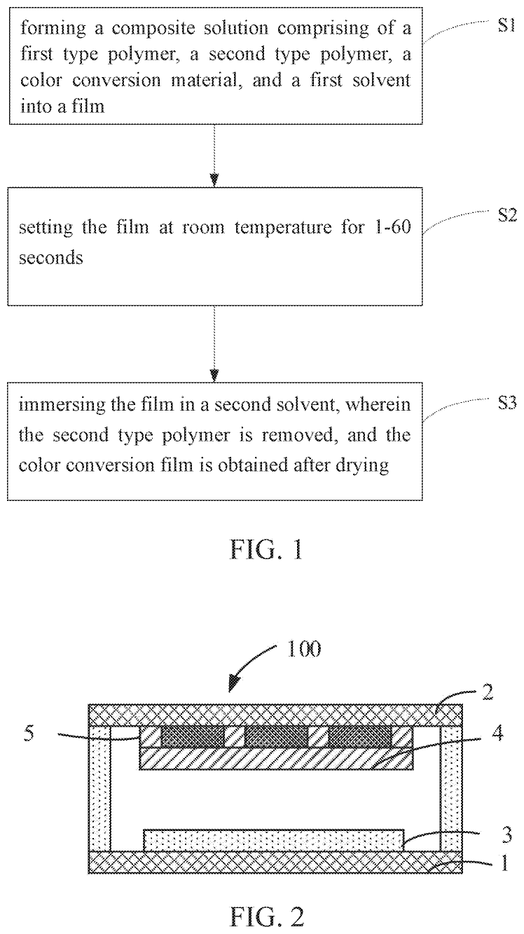

Please refer to FIG. 1, the method of manufacturing the color conversion film includes following steps:

S1, forming a composite solution comprising of a first type polymer, a second type polymer, a color conversion material, and a first solvent into a film.

The first type polymer is selected from a group consisting of water-soluble polymers and oil-soluble polymers. The second type polymer is selected from another group consisting of water-soluble polymers and oil-soluble polymers. The first type polymer includes at least one polymer. The second type polymer includes at least one polymer. The oil-soluble polymers can be, for example, selected from one or more of polyethylene terephthalate, polymethyl methacrylate, polystyrene, and the like. The water-soluble polymers can be, for example, selected from one or more of polyethylene glycol, polyvinyl alcohol, polyvinyl ether, polyethylene oxide, and the like.

In the present embodiment, the first type polymer is the oil-soluble polymers, the second type polymer is water-soluble polymers, and the color conversion material is an oil-soluble material.

The first type polymer is used to form a main structure of the film, that is, a skeleton of the film. The second type polymer is uniformly dispersed in the skeleton formed by the first type polymer. A mass fraction of the first type polymer is greater than a mass fraction of the second type polymer. The mass fraction of the first type polymer ranges from 10% to 25%, the mass fraction of the second type polymer ranges from 2% to 8%, and a mass fraction of the color conversion material ranges from 1% to 10%. The mass fraction of the first type polymer refers to a sum of the mass fraction of all the first type polymers. The mass fraction of the second type polymer refers to a sum of the mass fraction of all the second type polymers.

In other embodiments of the present application, the first type polymer is water-soluble polymers, the second type polymer is oil-soluble polymers, and the color conversion material is a water-soluble material.

The color conversion material can be a color conversion material commonly used in the display field, such as phosphors, quantum dots, or perovskite materials.

The first solvent can simultaneously dissolve the first type polymer, the second type polymer, and the color conversion material. The first solvent can be a polar aprotic solvent, for example, selected from dimethylformamide, acetone, acetonitrile, and the like.

The abovementioned composite solution is made into the film by a wet process. The so-called wet process refers to blade coating, spin coating, and screen printing, etc.

In that film, the first type polymer and the second type polymer are thoroughly mixed to form a uniform continuous-phase film. The second type polymer is uniformly dispersed in the skeleton formed by the first type polymer, and the color conversion material is embedded in the uniform continuous-phase film.

S3, immersing the film in a second solvent, wherein the second type polymer is removed, and the color conversion film is obtained after drying.

The second solvent can dissolve the second type polymer, but not the first type polymer and the color conversion material.

In the present embodiment, the second solvent is an aqueous solvent. The second solvent can be, for example, a polar protic solvent, and the polar protic solvent can be selected from water, methanol, ethanol, and the like.

In other embodiments of the present application, the first type polymer is the water-soluble polymers, the second type polymer is the oil-soluble polymers, and the color conversion material is a water-soluble material. The second solvent is an oily solvent and can be selected from chloroform, methylene chloride, and the like.

When the uniform continuous-phase film is immersed in the second solvent, the second solvent dissolves the second type polymer, replacing its position in the skeleton formed by the first type polymer, and forming a new uniform continuous-phase film with the first type polymer. The second solvent does not dissolve the color conversion material, and the color conversion material is still embedded in the skeleton formed by the first type polymer. The newly formed film is taken out of the polar protic solvent, dried to remove the second solvent in the film, and pores are formed at position originally occupied by the second solvent, to obtain a color conversion film.

The color conversion film manufactured by the abovementioned method has a porous skeleton composed of the first type polymer and the color conversion material embedded in the pores of the porous skeleton.

In addition, in an embodiment, the method of manufacturing the color conversion film further includes step S2, setting the film at room temperature for 1-60 seconds before immersing the film in the polar protic solvent. Since the first solvent used to make the film has a dissolving effect on the first type polymer, the first solvent remaining in the film can continue to dissolve the first type polymer even in an environment having the second solvent. Therefore, the film is set at room temperature in a period of time to evaporate the first solvent remaining in the film. The placement time affects the pore size and distribution uniformity of the pore size of the color conversion film to be formed subsequently. Setting the film at room temperature for 1-60 seconds can ensure the better configuration of the color conversion film.

Referring to FIG. 2, a second embodiment of the present application further provides a display panel 100 including a first substrate 1, a second substrate 2, and a blue light-emitting layer 3 and a color conversion film 4 disposed between the first substrate 1 and the second substrate 2. The color conversion film 4 is provided on a light-outputting surface of the blue light-emitting layer 3. In an embodiment, the color conversion film 4 is provided on the first substrate 1. The blue light-emitting layer 4 is provided on the second substrate 2. The display panel 100 further includes a color filter layer 5 disposed between the first substrate 1 and the color conversion film 4. In another embodiment, the blue light-emitting layer 3 and the color conversion film 4 both can be disposed on the second substrate 2.

The blue light-emitting layer 3 includes blue organic light-emitting diode devices or blue micro light-emitting diode devices.

The color conversion film 1 has a porous skeleton composed of a first type polymer and a color conversion material embedded in the pores of the porous skeleton. The color conversion material can be a color conversion material commonly used in the display field, such as phosphors, quantum dots, or perovskite materials. For the type of the first type polymer, refer to the first embodiment, which will not be repeated here.

Compared with the conventional art, the method of manufacturing a color conversion film of the present application uses two types of polymers with a color conversion material and a first solvent to form a composite solution to construct a uniform and continuous film, and one type of mixture is removed by a second solvent to form pores in the film, while the color conversion material remains in the pores. The continuous, uniform, and loose porous structure can enhance the color conversion material, such as the absorption of incident light by the color conversion material. At the same time, it can increase the light extraction rate of the excitation light of the color conversion material, and has a significant effect on improving the light efficiency of a color conversion film layer.

The above provides a detailed introduction to the embodiments of the present application. The present document uses specific embodiments to explain principles and implementation of the application. Descriptions of above embodiments are only used to help understand technical solutions and core ideas of the application. A person skilled in the art can make various modifications and changes to the above embodiments without departing from the technical idea of the present invention, and such variations and modifications are intended to be within the scope of the invention.

1. A method of manufacturing a color conversion film, comprising following steps:
forming a composite solution comprising of a first type polymer, a second type polymer, a color conversion material, and a first solvent into a film, wherein the first type polymer is selected from a group consisting of water-soluble polymers and oil-soluble polymers, and the second type polymer is selected from another group consisting of water-soluble polymers and oil-soluble polymers; and
immersing the film in a second solvent, wherein the second type polymer is removed, and the color conversion film is obtained after drying.

2. The method of manufacturing the color conversion film according to claim 1, wherein a mass fraction of the first type polymer is greater than a mass fraction of the second type polymer.

3. The method of manufacturing the color conversion film according to claim 1, wherein the first type polymer is the oil-soluble polymers, the second type polymer is the water-soluble polymers, and the color conversion material is an oil-soluble material.

4. The method of manufacturing the color conversion film according to claim 2, wherein the mass fraction of the first type polymer ranges from 10% to 25%, the mass fraction of the second type polymer ranges from 2% to 8%, and a mass fraction of the color conversion material ranges from 1% to 10%.

5. The method of manufacturing the color conversion film according to claim 3, wherein the first solvent is a polar aprotic solvent, and the second solvent is a polar protic solvent.

6. The method of manufacturing the color conversion film according to claim 1, wherein the first type polymer is the water-soluble polymers, the second type polymer is the oil-soluble polymers, and the color conversion material is a water-soluble material.

7. The method of manufacturing the color conversion film according to claim 1, wherein the oil-soluble polymers are selected from one or more of polyethylene terephthalate, polymethyl methacrylate, and polystyrene.

8. The method of manufacturing the color conversion film according to claim 1, wherein the water-soluble polymers are selected from one or more of polyethylene glycol, polyvinyl alcohol, polyvinyl ether, and polyethylene oxide.

9. A color conversion film, wherein the color conversion film comprises a porous skeleton composed of a first type polymer and a color conversion material embedded in pores of the porous skeleton, and the first type polymer is selected from a group consisting of water-soluble polymers and oil-soluble polymers.

10. The color conversion film according to claim 9, wherein the first type polymer is the oil-soluble polymers, and the color conversion material is an oil-soluble material.

11. The color conversion film according to claim 9, wherein the first type polymer is the water-soluble polymers, and the color conversion material is a water-soluble material.

12. The color conversion film according to claim 9, wherein the oil-soluble polymers are selected from one or more of polyethylene terephthalate, polymethyl methacrylate, and polystyrene.

13. The color conversion film according to claim 9, wherein the water-soluble polymers are selected from one or more of polyethylene glycol, polyvinyl alcohol, polyvinyl ether, and polyethylene oxide.

14. A display panel, comprising a first substrate, a second substrate, and a blue light-emitting layer and a color conversion film disposed between the first substrate and the second substrate, wherein the color conversion film is disposed on a light-outputting surface of the blue light-emitting layer, the color conversion film comprises a porous skeleton composed of a first type polymer and a color conversion material embedded in pores of the porous skeleton, and the first type polymer is selected from a group consisting of water-soluble polymers and oil-soluble polymers.

15. The display panel according to claim 14, wherein the first type polymer is the oil-soluble polymers, and the color conversion material is an oil-soluble material.

16. The display panel according to claim 14, wherein the first type polymer is the water-soluble polymers, and the color conversion material is a water-soluble material.

17. The display panel according to claim 14, wherein the oil-soluble polymers are selected from one or more of polyethylene terephthalate, polymethyl methacrylate, and polystyrene.

18. The display panel according to claim 14, wherein the water-soluble polymers are selected from one or more of polyethylene glycol, polyvinyl alcohol, polyvinyl ether, and polyethylene oxide.
